(19) United States
(12) Patent Application Publication
(10) Pub. No.: US 2006/0170040 A1
(43) Pub. Date: Aug. 3, 2006

(54) Semiconductor device, semiconductor integrated circuit device, and semiconductor device fabrication method

(75) Inventor: Youichi Momiyama, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/127,251

(22) Filed: May 12, 2005

(30) Foreign Application Priority Data
Jan. 28, 2005 (JP) 2005-020875

(51) Int. Cl. H01L 29/76

(52) U.S. Cl. 257/335

(57) ABSTRACT

A semiconductor device that can operate at plural kinds of power supply voltages. A pocket region which is adjacent to a source region and the conduction type of which is the same as that of a channel region formed between the source region and a drain region is formed. By doing so, an asymmetrical profile of impurity concentration in which impurity concentration on a source-region side of a region between the source region and the drain region is high and in which impurity concentration on a drain-region side of the region between the source region and the drain region is low is obtained. As a result, an electric current generated by impact ionization at the time of a drain bias being applied decreases. Therefore, a deterioration in the characteristics of the semiconductor device caused by hot carriers can be reduced. That is to say, the semiconductor device's resistance to hot carriers improves, so the semiconductor device can operate at the plural kinds of power supply voltages.

### CROSS-REFERENCE TO RELATED APPLICATIONS

This application is based upon and claims the benefits of priority from the prior Japanese Patent Application No. 2005-020875, filed on Jan. 28, 2005, the entire contents of which are incorporated herein by reference.

### BACKGROUND OF THE INVENTION

1. Field of the Invention

This invention relates to a semiconductor device, a semiconductor integrated circuit device and a method for fabricating such a semiconductor device and, more particularly, to a semiconductor device and a semiconductor integrated circuit device used in an environment in which a plural kinds of power supply voltages are used and a method for fabricating such a semiconductor device.

2. Description of the Related Art

In recent years the necessity for system large scale integration (LSI) and the like having the function of communicating with various external devices has risen. Conventional external devices operate at a power supply voltage of, for example, 1.8, 2.5, or 3.3 V. That is to say, the power supply voltages of the conventional external devices differ among different generations. Where LSI, for example, communicates with the conventional external devices, more particularly with noncommercial devices, such necessity rises. Therefore, with conventional LSI, transistors the characteristics of which are optimized according to the power supply voltages of external devices with which the LSI communicates are often formed on one chip.

By the way, the occurrence of hot carriers contributes to a deterioration in the characteristics of a transistor. Conventionally, the formation of a structure in which a profile of the concentration of impurities introduced is asymmetrical with respect to a gate electrode (for example, a structure having a pocket region and a lightly doped drain (LDD) region in which impurity concentration on the source region side differs from impurity concentration on the drain region side) has been proposed as a method for reducing such a deterioration due to the occurrence of hot carriers (see Japanese Unexamined Patent Publication No. 2003-45993).

As stated above, in semiconductor integrated circuit devices, such as LSI, which communicate with external devices which operate at different power supply voltages, usually the most suitable transistor structure for each power supply voltage from the viewpoints of a driving current and reliability is formed.

### SUMMARY OF THE INVENTION

The present invention was made under the background circumstances described above. An object of the present invention is to provide a semiconductor device capable of operating at plural kinds of power supply voltages and a method for fabricating such a semiconductor device.

Another object of the present invention is to provide a semiconductor integrated circuit device in which such semiconductor devices are integrated.

In order to achieve the above-mentioned first object, a semiconductor device comprising a gate electrode formed above a semiconductor substrate with a gate insulator between and a source region and a drain region formed in the semiconductor substrate is provided. In an impurity concentration profile of this semiconductor device, impurity concentration on a source-region side of a region between the source region and the drain region is higher than impurity concentration on a drain-region side of the region between the source region and the drain region.

Furthermore, in order to achieve the above-mentioned second object, a semiconductor integrated circuit device comprising a plurality of semiconductor devices each including a gate electrode formed above a semiconductor substrate with a gate insulator between and a source region and a drain region formed in the semiconductor substrate is provided. In this semiconductor integrated circuit device, the plurality of semiconductor devices in each of which impurity concentration on a source-region side of a region between the source region and the drain region is higher than impurity concentration on a drain-region side of the region between the source region and the drain region are connected to power supply lines corresponding to plural kinds of power supply voltages.

In addition, in order to achieve the above-mentioned second object, a method for fabricating semiconductor devices which are included in a semiconductor integrated circuit device, each of which includes a gate electrode formed above a semiconductor substrate with a gate insulator between and a source region and a drain region formed in the semiconductor substrate, and which are connected to power supply lines corresponding to plural kinds of power supply voltages is provided. This method for fabricating the semiconductor devices comprises the steps of introducing impurities for controlling threshold voltage into the semiconductor substrate; forming the gate insulator with thickness corresponding to thickness required at the time of operation at a lowest power supply voltage of the plural kinds of power supply voltages on the semiconductor substrate in the case of a profile of impurity concentration in a region between the source region and the drain region in each of the semiconductor devices being approximately constant; forming the gate electrode on the gate insulator; introducing impurities into the semiconductor substrate with the gate electrode as a mask so that impurity concentration on a source-region side of the region between the source region and the drain region is higher than impurity concentration on a drain-region side of the region between the source region and the drain region at the time of the source region and the drain region being formed; forming spacers on sidewalls of the gate electrode; and introducing impurities into the semiconductor substrate with the gate electrode and the spacers as masks to form the source region and the drain region.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 shows an example of the structure of the main portion of a transistor in which a profile of impurity concentration is asymmetrical.

FIG. 2 shows the relationship between a driving current and a maximum substrate current value.

FIG. 3 shows an example of the structure of the main portion of an LSI.

FIG. 4 is a simplified sectional view showing the main portion of a first gate insulator formation step.

FIG. 5 is a simplified sectional view showing the main portion of a first etching step.

FIG. 6 is a simplified sectional view showing the main portion of a second gate insulator formation step.

FIG. 7 is a simplified sectional view showing the main portion of a gate electrode formation step.

FIG. 8 is a simplified sectional view showing the main portion of an LDD region and asymmetrical pocket region formation step.

FIG. 9 is a simplified sectional view showing the main portion of a pocket region formation step.

FIG. 10 is a simplified sectional view showing the main portion of a conventional first gate insulator formation step.

FIG. 11 is a simplified sectional view showing the main portion of a conventional first etching step.

FIG. 12 is a simplified sectional view showing the main portion of a conventional second gate insulator formation step.

FIG. 13 is a simplified sectional view showing the main portion of a conventional second etching step.

FIG. 14 is a simplified sectional view showing the main portion of a conventional third gate insulator formation step.

FIG. 15 is a simplified sectional view showing the main portion of a conventional first LDD region formation step.

FIG. 16 is a simplified sectional view showing the main portion of a conventional second LDD region formation step.

FIG. 17 is a simplified sectional view showing the main portion of a conventional LDD region and pocket region formation step.

FIG. 18 is a simplified sectional view showing the main portion of a conventional spacer formation step.

FIG. 19 is a simplified sectional view showing the main portion of a conventional source region and drain region formation step.

### DESCRIPTION OF THE PREFERRED EMBODIMENTS

A conventional method for forming a semiconductor integrated circuit device will now be described. The description will be given with the case where three kinds of transistors, that is to say, an internal transistor, a 2.5V I/O transistor, and a 3.3V I/O transistor are formed on one Si substrate to fabricate LSI as an example. In each transistor formed, it is assumed that impurity concentration in a region between a source region and a drain region is approximately constant and that a profile of impurity concentration is symmetrical. Usually a CMOS structure is adopted for forming LSI. In this case, however, a method for forming an nMOS will be described for the sake of simplicity. Descriptions of a method for forming a pMOS will be omitted.

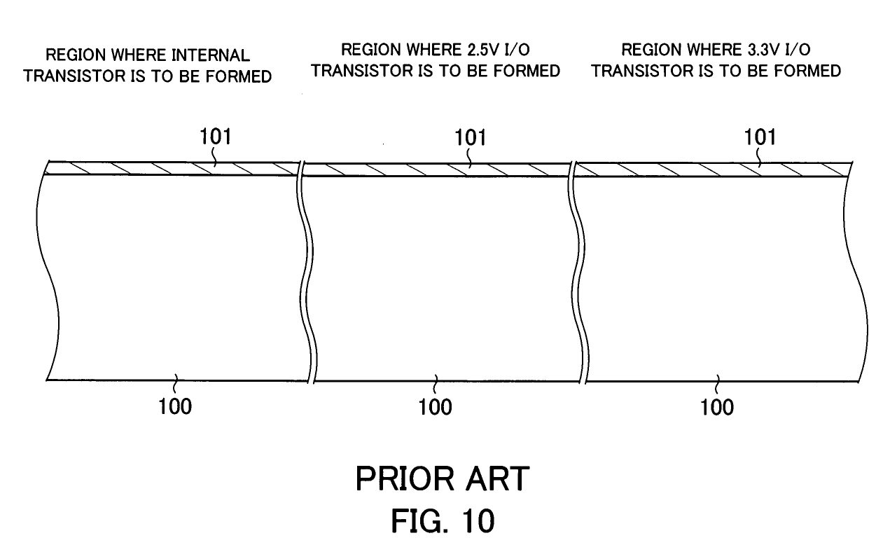

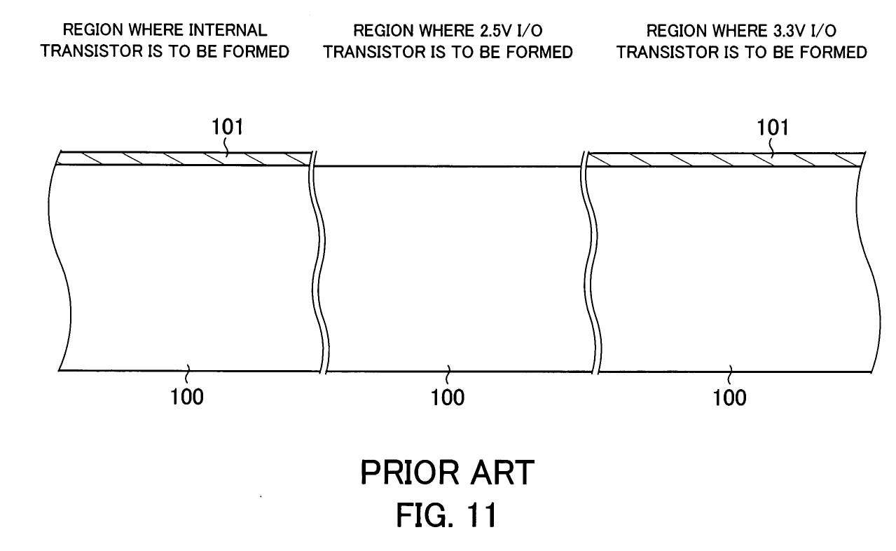

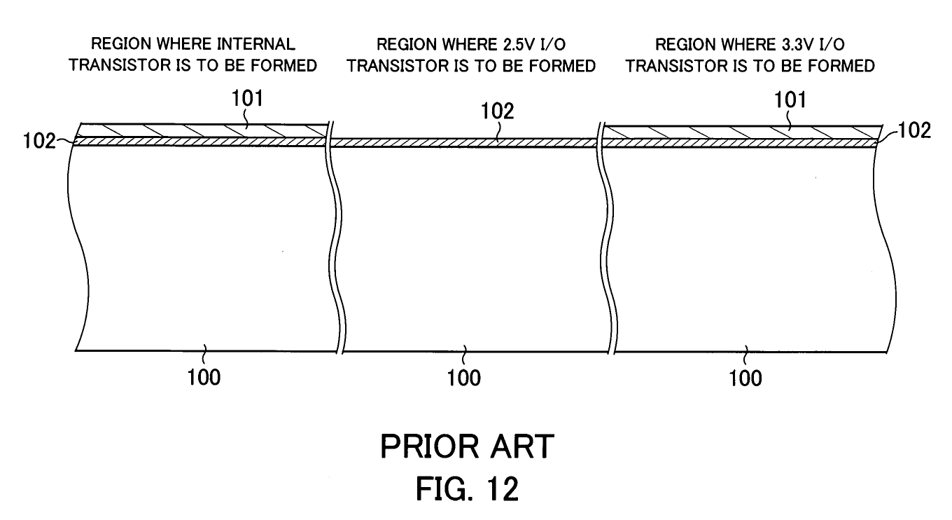

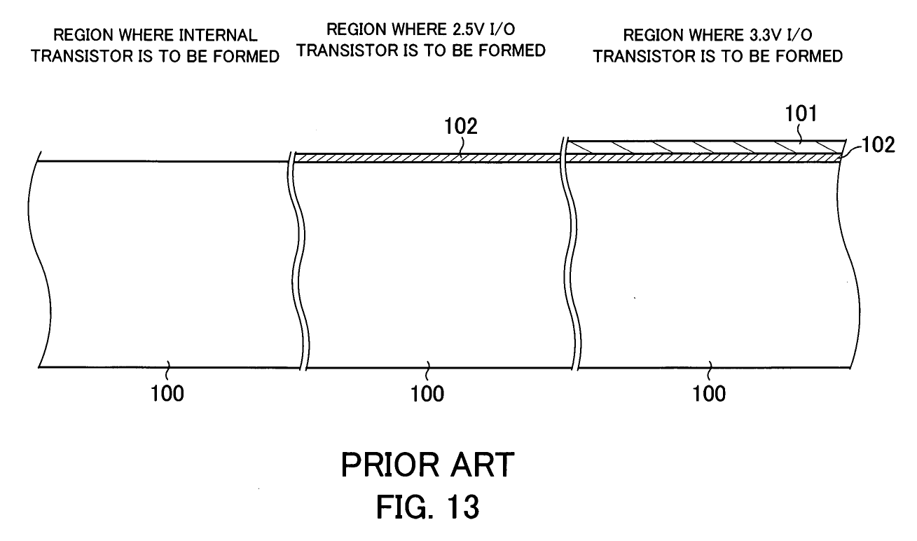

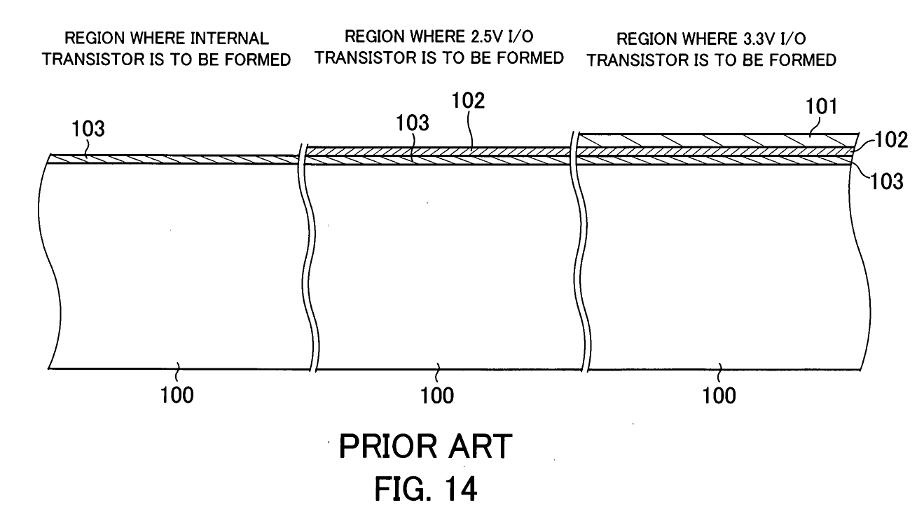

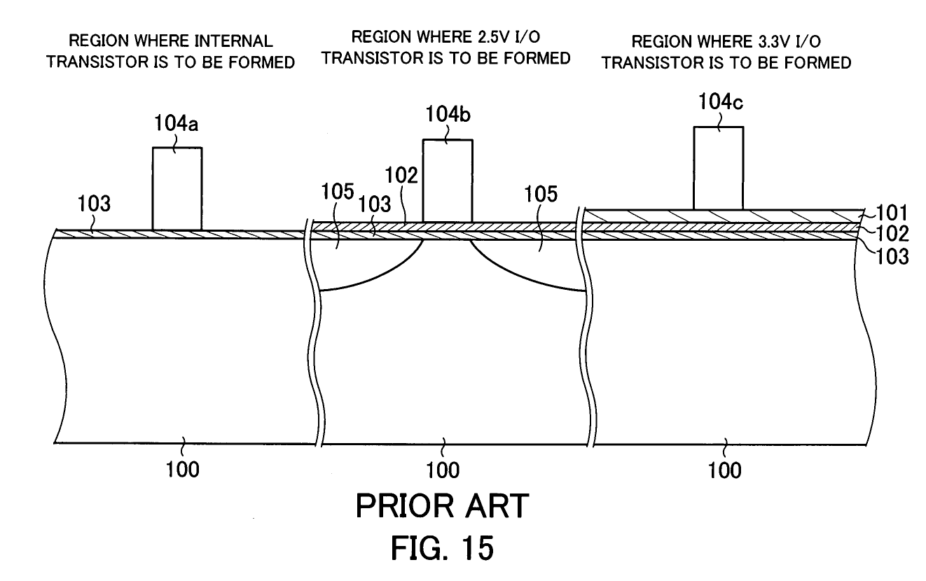

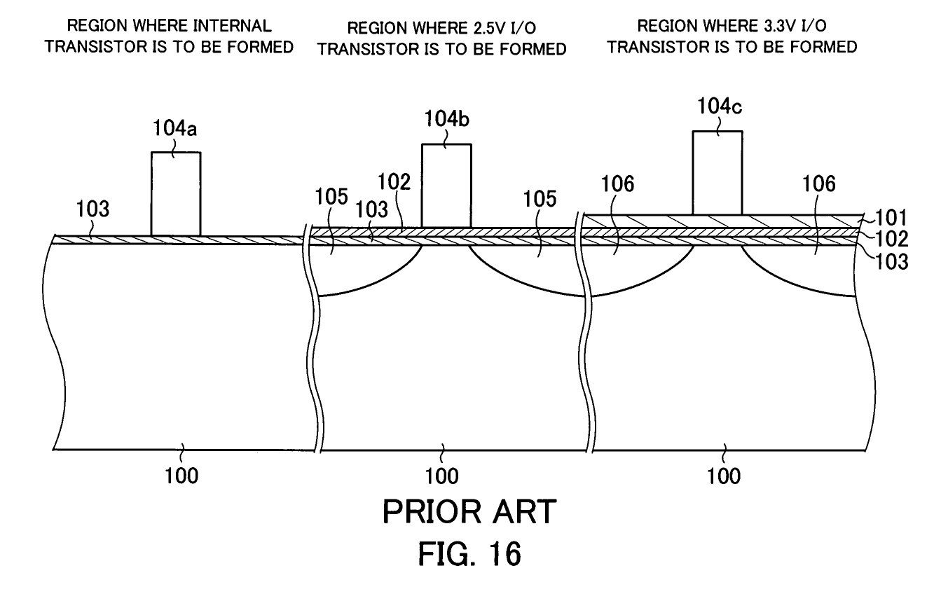

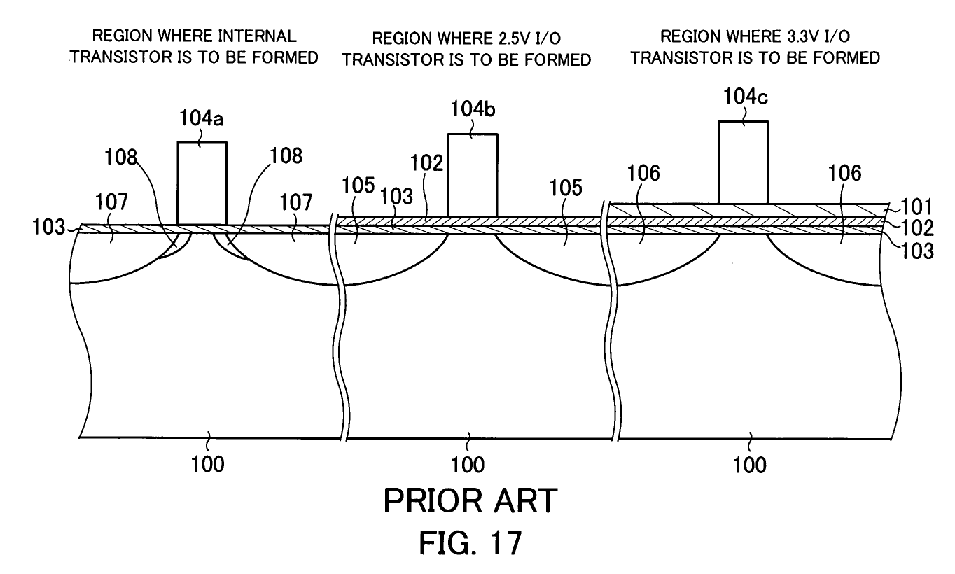

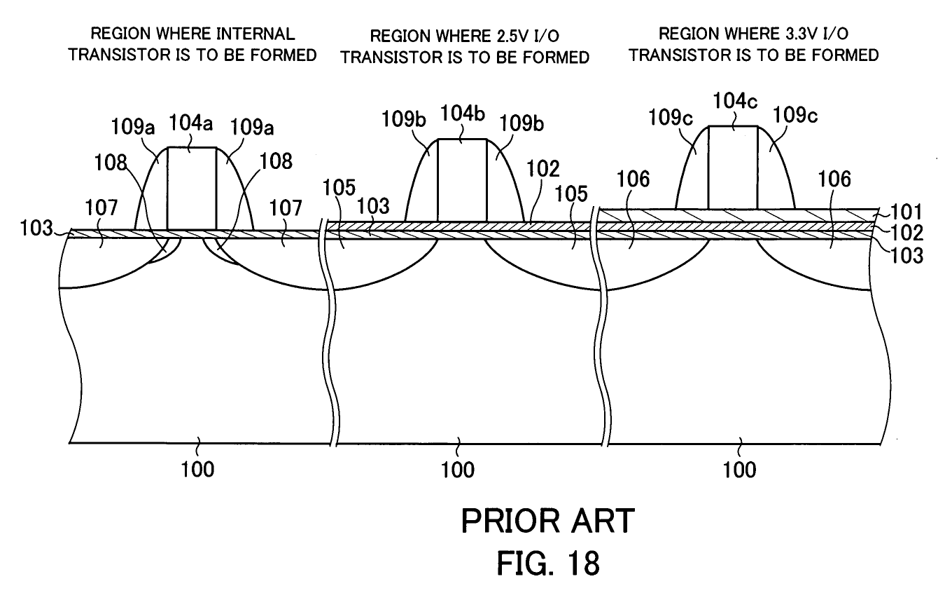

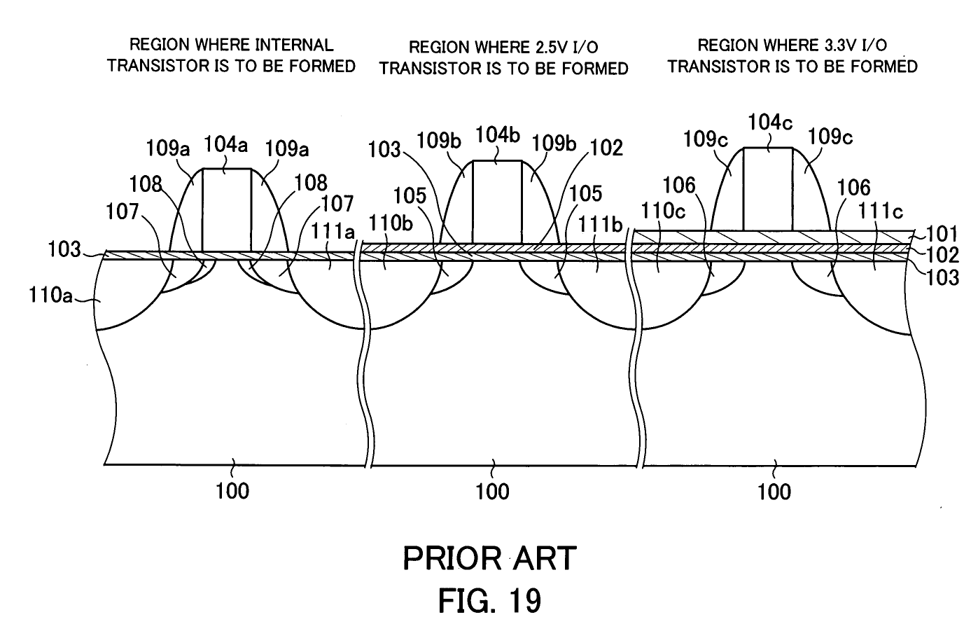

FIGS. 10 through 19 are views for describing an example of a conventional formation method. FIG. 10 is a simplified sectional view showing the main portion of a conventional first gate insulator formation step. FIG. 11 is a simplified sectional view showing the main portion of a conventional first etching step. FIG. 12 is a simplified sectional view showing the main portion of a conventional second gate insulator formation step. FIG. 13 is a simplified sectional view showing the main portion of a conventional second etching step. FIG. 14 is a simplified sectional view showing the main portion of a conventional third gate insulator formation step. FIG. 15 is a simplified sectional view showing the main portion of a conventional first LDD region formation step. FIG. 16 is a simplified sectional view showing the main portion of a conventional second LDD region formation step. FIG. 17 is a simplified sectional view showing the main portion of a conventional LDD region and pocket region formation step. FIG. 18 is a simplified sectional view showing the main portion of a conventional spacer formation step. FIG. 19 is a simplified sectional view showing the main portion of a conventional source region and drain region formation step. Each step will now be described in order with reference to FIGS. 10 through 19.

First, isolation regions (not shown) are formed by a shallow trench isolation (STI) method and Vth control implantation for controlling the threshold voltage of each transistor is performed in regions where an internal transistor, a 2.5V I/O transistor, and a 3.3V I/O transistor are to be formed. This Vth control implantation is performed by implanting, for example, boron (B) ions under conditions suitable for each transistor.

As shown in FIG. 10, the entire surface of an Si substrate 100 is then oxidized to form an SiO₂ film 101 in the regions where the internal transistor, the 2.5V I/O transistor, and the 3.3V I/O transistor are to be formed. After that, as shown in FIG. 11, the regions where the internal transistor and the 3.3V I/O transistor are to be formed are coated with a resist to form resist films (not shown). Etching is performed with the resist films as masks to remove the SiO₂ film 101 in the region where the 2.5V I/O transistor is to be formed. The resist films are then stripped off. Next, as shown in FIG. 12, the entire surface of the Si substrate 100 is oxidized again to form an SiO₂ film 102. After that, as shown in FIG. 13, resist films (not shown) are formed in the regions where the 2.5V I/O transistor and the 3.3V I/O transistor are to be formed. Etching is performed with the resist films as masks to remove the SiO₂ films 101 and 102 in the region where the internal transistor is to be formed. The resist films are then stripped off. Next, as shown in FIG. 14, the entire surface of the Si substrate 100 is oxidized to form an SiO₂ film 103.

By performing the above-mentioned steps, the total thickness of the SiO₂ films 102 and 103 formed in the region where the 2.5V I/O transistor is to be formed is, for example, about 5 nm and the total thickness of the SiO₂ films 101, 102, and 103 formed in the region where the 3.3V I/O transistor is to be formed is, for example, about 7 nm.

After that, as shown in FIG. 15, gate electrodes 104a, 104b, and 104c of the internal transistor, the 2.5V I/O transistor, and the 3.3V I/O transistor, respectively, are formed. Resist films (not shown) are formed in the regions where the internal transistor and the 3.3V I/O transistor are to be formed, and phosphorus (P) ions, for example, are implanted in the region where the 2.5V I/O transistor is to be formed under predetermined conditions to form LDD regions 105. The resist films are then stripped off. Similarly, as shown in FIG. 16, resist films (not shown) are formed in the regions where the internal transistor and the 2.5V I/O transistor are to be formed, and LDD regions 106 are formed in the region where the 3.3V I/O transistor is to be formed. The resist films are then stripped off. Moreover, as shown in FIG. 17, resist films (not shown) are formed in the regions where the 2.5V I/O transistor and the 3.3V I/O transistor are to be formed. In the region where the internal transistor is to be formed, arsenic ions, for example, are implanted under predetermined conditions to form LDD regions 107 and then boron ions, for example, are implanted under predetermined conditions to form pocket regions 108. The resist films are then stripped off.

Next, as shown in FIG. 18, spacers 109a, 109b, and 109c are formed on the sidewalls of the gate electrodes 104a, 104b, and 104c, respectively. As shown in FIG. 19, source regions 110a, 110b, and 110c and drain regions 111a, 111b, and 111c are formed with the spacers 109a, 109b, and 109c as masks. The subsequent steps are the same as those performed in the ordinary CMOS formation method.

As stated above, usually the gate insulators of the most suitable transistors for different power supply voltages differ in thickness. In the above-mentioned case, the gate insulators are formed by oxidizing the Si substrate. The SiO₂ film 103 (one layer) functions as a gate insulator in the internal transistor, the SiO₂ films 102 and 103 (two layers) function as a gate insulator in the 2.5V I/O transistor, and the SiO₂ films 101, 102, and 103 (three layers) function as a gate insulator in the 3.3V I/O transistor.

To form plural kinds of transistors optimized according to power supply voltages on one chip, they must be fabricated separately. Therefore, the formation and removal of a gate insulator must be repeated, resulting in an increase in process and chip costs. Moreover, even if the formation of the plural kinds of transistors with different gate insulator thicknesses on the one chip is possible in terms of the costs, the following problems will arise in the manufacturing process.

First, in order to form an nMOS, Vth control implantation is performed in, for example, the above-mentioned way by implanting boron ions and then the Si substrate 100 is oxidized. In this case, the boron ions implanted diffuse into the SiO₂ films 101, 102, and 103 while they are being formed. As a result, the final impurity concentration in a channel lowers. This is fatal especially to low standby power (LSTP) devices. Accordingly, Vth control implantation must be performed with such a decrease in impurity concentration in the channel taken into consideration. In this case, however, it is difficult to set impurity concentration in the channel to a desired value. For example, if the first impurity concentration in the channel is set to a high value with a decrease in impurity concentration in the channel taken into consideration, impurity concentration in the surface of the Si substrate may become a proper value through oxidation steps and the like. However, impurity concentration at the junction of the channel region and a source region and the junction of the channel region and a drain region which are in comparatively deep positions in the substrate remains high, resulting in an increase in junction leakage current. Secondly, when an STI region is formed in the Si substrate 100, the shoulder of an Si active region on the Si substrate 100 tends to get exposed at the edge of the STI region. As a result, a parasitic transistor tends to have an influence. A hump may appear in a subthreshold region according to circumstances. Thirdly, a resist coating and stripping step must be performed more than one time to form the gate insulators with different thicknesses. Accordingly, reliability estimated on the basis of the time dependent dielectric breakdown (TDDB) and the like deteriorates.

Thus an attempt to, for example, reduce the number of kinds of and the number of transistors formed on one chip by making a high power supply voltage transistor operate both at a high power supply voltage and at a low power supply voltage is currently made. It is assumed that an ordinary transistor structure in which a profile of impurity concentration is symmetrical is adopted. To make one transistor operate both at a high power supply voltage and at a low power supply voltage in this way, transistor design must be made on the basis of the high power supply voltage from the viewpoint of reliability. However, when such a high power supply voltage transistor is actually made to operate at a low power supply voltage, malfunction occurs at operating time. For example, a sufficient driving current cannot be gained and high-speed operation cannot be performed.

Embodiments of the present invention will now be described in detail with reference to the drawings.

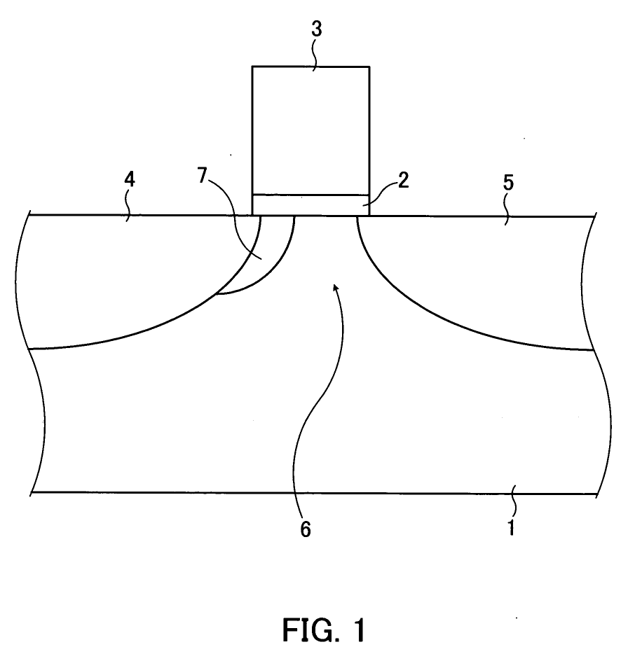

FIG. 1 shows an example of the structure of the main portion of a transistor in which a profile of impurity concentration is asymmetrical.

A transistor shown in FIG. 1 includes a gate electrode 3 formed above a semiconductor substrate 1 with a gate insulator 2 between and a source region 4 and a drain region 5 formed in the semiconductor substrate 1 on both sides of the gate electrode 3. This transistor also includes a pocket region 7 which is adjacent to the source region 4 and the conduction type of which is the same as that of a channel region 6 formed between the source region 4 and the drain region 5. As stated above, a profile of impurity (channel impurity) concentration in the transistor shown in FIG. 1 is asymmetrical. That is to say, impurity concentration on a source region 4 side of a region between the source region 4 and the drain region 5 is high and impurity concentration on a drain region 5 side of the region between the source region 4 and the drain region 5 is low.

With such a transistor in which a profile of impurity concentration is asymmetrical, an electric current generated by impact ionization at the time of a drain bias being applied decreases. Therefore, a deterioration in the characteristics of the transistor caused by hot carriers can be reduced.

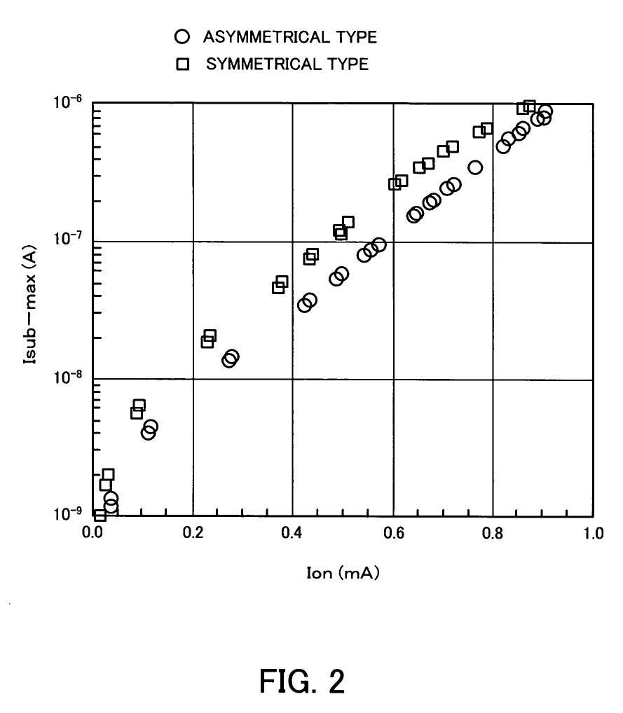

FIG. 2 shows the relationship between a driving current and a maximum substrate current value. In FIG. 2, a horizontal axis indicates driving current Ion (mA) and a vertical axis indicates maximum substrate current value Isub-max (A). FIG. 2 also shows the relationship between driving current Ion and maximum substrate current value Isub-max in a transistor (shown by circles) in which a profile of impurity concentration in a region between a source region and a drain region is asymmetrical and the relationship between driving current Ion and maximum substrate current value Isub-max in a transistor (shown by squares) in which a profile of impurity concentration in a region between a source region and a drain region is symmetrical.

There is a strong correlation between a deterioration in the characteristics of the transistor caused by hot carriers and the number of hot carriers generated by impact ionization in an edge portion of the drain region 5. Accordingly, by decreasing a substrate current, a deterioration in the characteristics of the transistor can be reduced and its life can be lengthened.

As can be seen from FIG. 2, if driving currents Ion in the two transistors are the same, maximum substrate current value Isub-max in the transistor (asymmetrical type transistor) in which a profile of impurity concentration in the region between the source region and the drain region is asymmetrical is smaller than maximum substrate current value Isub-max in the transistor (symmetrical type transistor) in which a profile of impurity concentration in the region between the source region and the drain region is symmetrical. That is to say, in the asymmetrical type transistor, impact ionization occurs with less frequency, a deterioration in the characteristics caused by hot carriers is reduced more significantly, and its life can be lengthened more. Seen from another standpoint, driving current Ion in the asymmetrical type transistor can be set to a greater value if the same life is guaranteed. In other words, the asymmetrical type transistor improves in resistance to hot carriers, so it can operate at a high power supply voltage at which impact ionization will occur with greater frequency in the symmetrical type transistor.

Therefore, such an asymmetrical type transistor can operate at plural kinds of power supply voltages. For example, an I/O transistor which can operate at power supply voltages of 2.5V and 3.3V can be formed. If an LSI chip is formed by using such a transistor structure, the number of kinds of and the number of transistors formed on it can be reduced, resulting in a reduction in the process and chip costs. In addition, the manufacturing process can be simplified by reducing the number of steps for forming gate insulators with different thicknesses according to power supply voltages. Therefore, costs, such as a process cost, can be reduced and a deterioration in the characteristics of transistors caused by resist coating and stripping can be reduced.

Methods for making a profile of impurity concentration in a region in a transistor between source and drain regions asymmetrical are as follows. As shown in FIG. 1, the pocket region 7 which is adjacent to the source region 4 is formed. Two pocket regions which are adjacent to the source region 4 and the drain region 5, respectively, may be formed so that impurity concentration on the source region 4 side will be higher than impurity concentration on the drain region 5 side. An LDD region may be formed on the drain region 5 side. Two LDD regions may be formed on the source region 4 and drain region 5 sides, respectively, so that impurity concentration on the source region 4 side will be higher than impurity concentration on the drain region 5 side. A profile of impurity concentration in these pocket and LDD regions can be made asymmetrical. As stated above, by forming a transistor structure in which impurity concentration at the edge of a drain region is made low to lower electric field strength, the same effects that are described above can be obtained. For example, the transistor can operate at plural kinds of power supply voltages.

An example of the application of the above-mentioned transistor structure will now be described.

Descriptions will be given with the case where an LSI with a CMOS structure in which an internal transistor and a 2.5V and 3.3V I/O transistor are formed on one Si substrate is fabricated as an example.

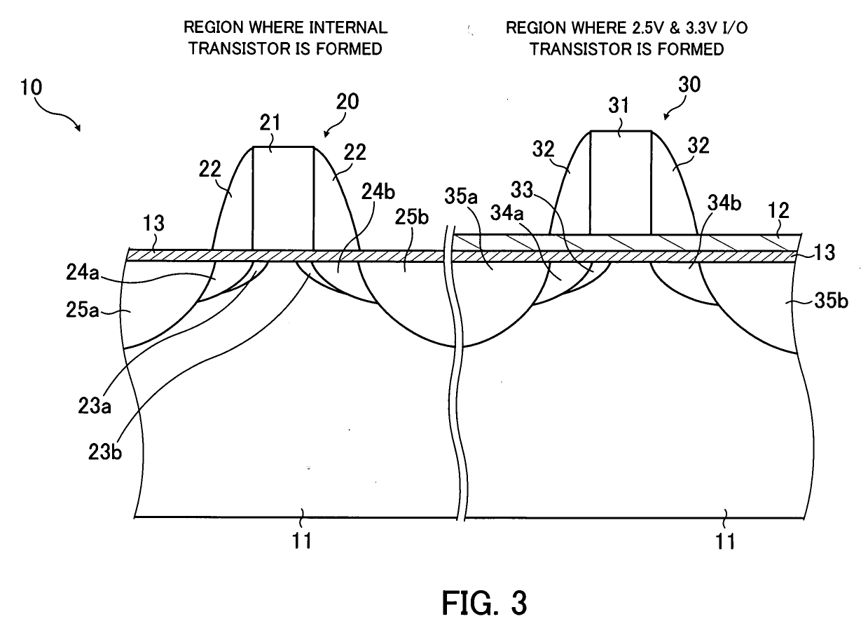

FIG. 3 shows an example of the structure of the main portion of an LSI. The actual LSI has a CMOS structure. In FIG. 3, however, only nMOSes are shown for the sake of simplicity.

An LSI 10 shown in FIG. 3 includes an internal transistor 20 and a 2.5V and 3.3V I/O transistor 30.

The internal transistor 20 includes a gate electrode 21 formed above an Si substrate 11 with an SiO₂ film 13 between and spacers 22 formed on sidewalls of the gate electrode 21. The internal transistor 20 also includes pocket regions 23a and 23b and LDD regions 24a and 24b formed in the Si substrate 11 by implanting ions with the gate electrode 21 as a mask. The pocket region 23a and the LDD region 24a are formed on the left-hand side of the gate electrode 21 and the pocket region 23b and the LDD region 24b are formed on the right-hand side of the gate electrode 21. In addition, the internal transistor 20 includes a source region 25a and a drain region 25b formed in the Si substrate 11 on the left-hand and right-hand sides, respectively, of the gate electrode 21 and the spacer 22 by implanting ions with the gate electrode 21 and the spacers 22 as masks. In the internal transistor 20 having the above-mentioned structure, the SiO₂ film 13 functions as a gate insulator.

The 2.5V and 3.3V I/O transistor 30 includes a gate electrode 31 formed above the Si substrate 11 with an SiO₂ film 12 and the SiO₂ film 13 between and spacers 32 formed on sidewalls of the gate electrode 31. The 2.5V and 3.3V I/O transistor 30 also includes a pocket region 33 and LDD regions 34a and 34b formed in the Si substrate 11 by implanting ions with the gate electrode 31 as a mask. The pocket region 33 is formed only on the left-hand side of the gate electrode 31 and the LDD regions 34a and 34b are formed on the left-hand and right-hand sides, respectively, of the gate electrode 31. In addition, the 2.5V and 3.3V I/O transistor 30 includes a source region 35a and a drain region 35b formed in the Si substrate 11 on the left-hand and right-hand sides, respectively, of the gate electrode 31 and the spacer 32 by implanting ions with the gate electrode 31 and the spacers 32 as masks. In the 2.5V and 3.3V I/O transistor 30 having the above-mentioned structure, the SiO₂ films 12 and 13 function as a gate insulator.

In the LSI 10 having the above-mentioned structure, the asymmetrical pocket region 33 is formed between the source region 35a and the drain region 35b in the 2.5V and 3.3V I/O transistor 30, so impurity concentration on a source region 35a side of a region between the source region 35a and the drain region 35b is high and impurity concentration on a drain region 35b side of the region between the source region 35a and the drain region 35b is low. As a result, when a drain bias is applied, frequency in the occurrence of impact ionization decreases. That is to say, a deterioration in the characteristics of the transistor caused by hot carriers can be reduced. Therefore, as stated above, a transistor which can operate at plural kinds of power supply voltages (the 2.5V and 3.3V I/O transistor 30, in this example) can be formed.

When the 2.5V and 3.3V I/O transistor 30 is formed, the gate insulator is formed so that its thickness will correspond to the lower power supply voltage, or 2.5V. To be concrete, the thickness of the gate insulator of the 2.5V and 3.3V I/O transistor 30 should be set to a value close to the standard thickness of the gate insulators of transistors which operate at 2.5V. In the 2.5V and 3.3V I/O transistor 30, the pocket region 33 is formed on the source region 35a side of the region between the source region 35a and the drain region 35b so that a profile of impurity concentration in the region between the source region 35a and the drain region 35b will be asymmetrical. Therefore, even if the gate insulator is formed thin in this way, the 2.5V and 3.3V I/O transistor 30 can operate at the higher power supply voltage, or 3.3V. In addition, with conventional LSIs, a 2.5V I/O transistor differs from a 3.3V I/O transistor in thickness of gate insulator. However, this does not apply to the 2.5V and 3.3V I/O transistor 30. As a result, the manufacturing process can be simplified and the process and chip costs can be reduced.

A method for fabricating the LSI 10 having the above-mentioned structure will now be described more concretely. A method for forming an nMOS will be described and descriptions of how to form a pMOS will be omitted.

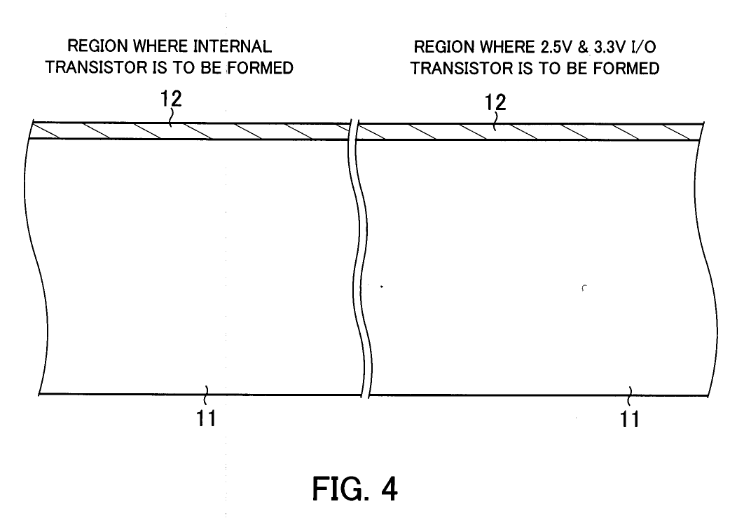

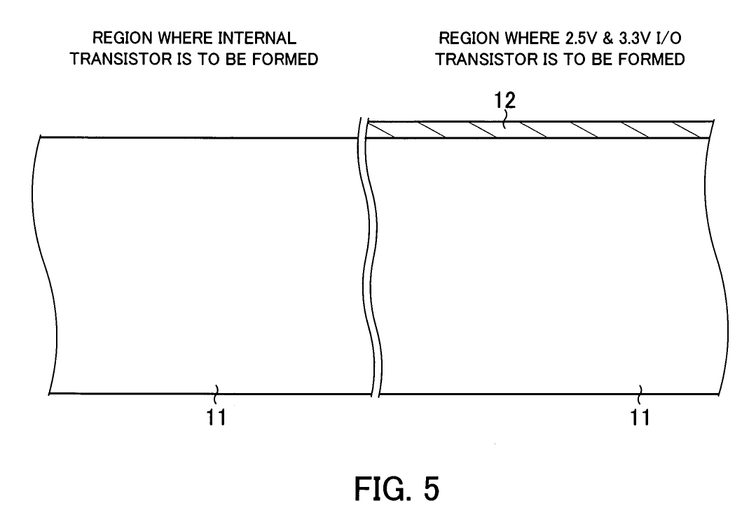

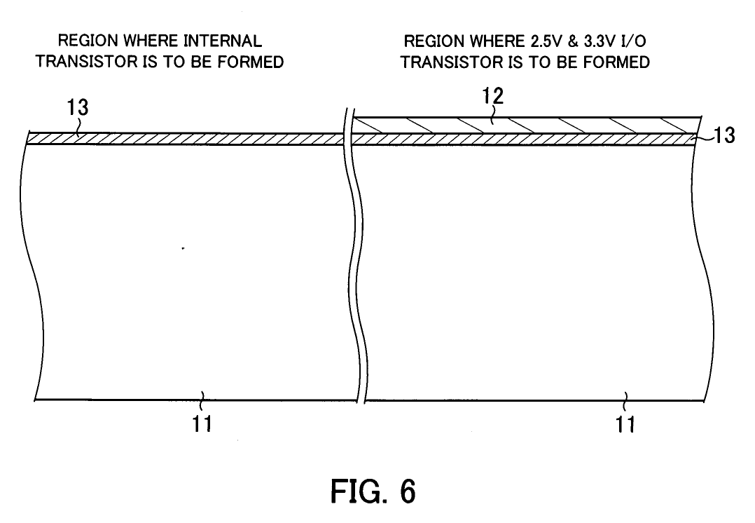

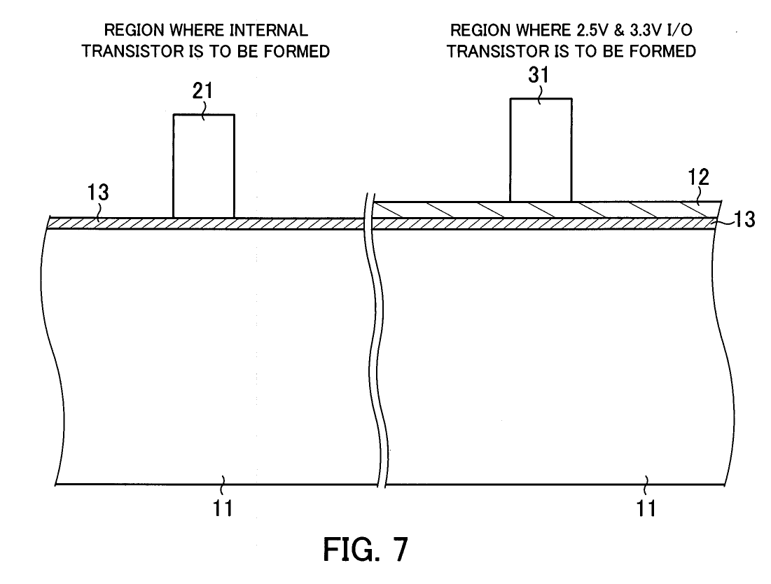

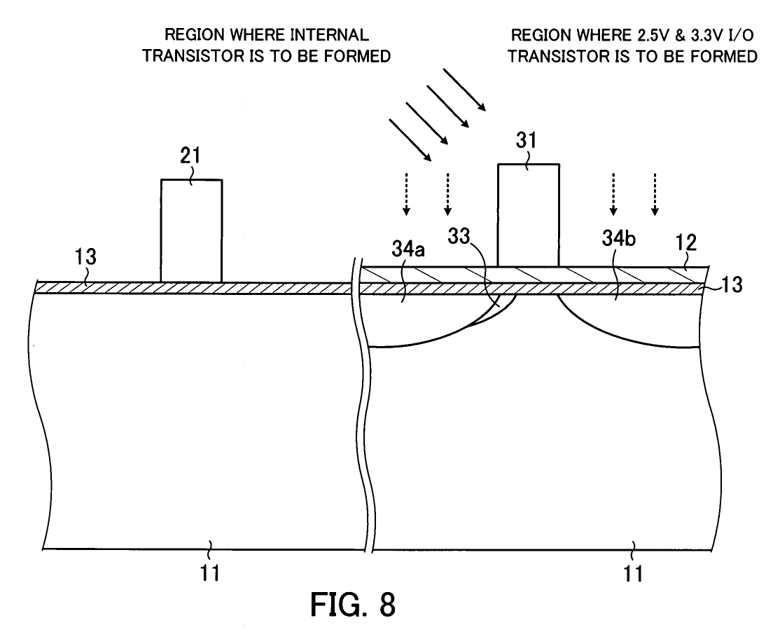

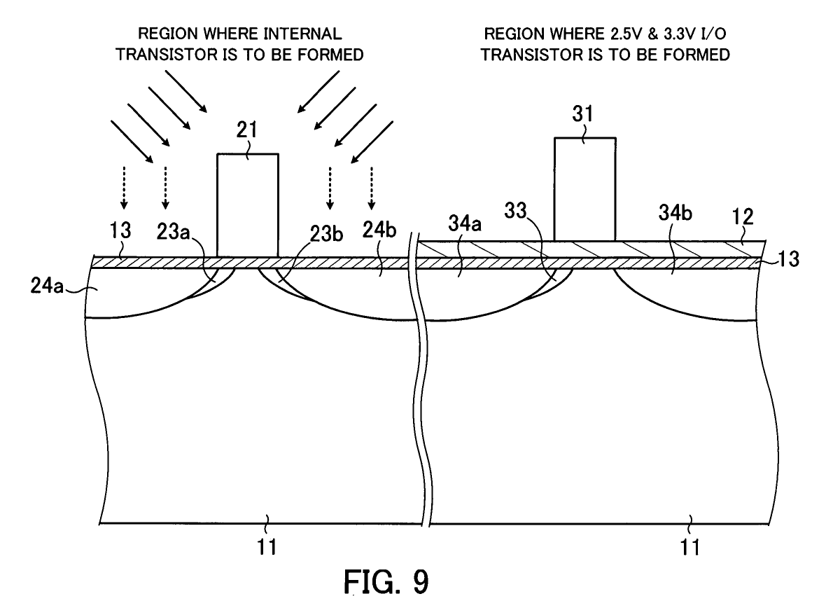

FIGS. 4 through 9 are views for describing an example of a method for fabricating the LSI 10. FIG. 4 is a simplified sectional view showing the main portion of a first gate insulator formation step. FIG. 5 is a simplified sectional view showing the main portion of a first etching step. FIG. 6 is a simplified sectional view showing the main portion of a second gate insulator formation step. FIG. 7 is a simplified sectional view showing the main portion of a gate electrode formation step. FIG. 8 is a simplified sectional view showing the main portion of an LDD region and asymmetrical pocket region formation step. FIG. 9 is a simplified sectional view showing the main portion of a pocket region formation step. In FIGS. 4 through 9, the same components that are shown in FIG. 3 are marked with the same symbols. Each step will now be described in order with reference to FIGS. 4 through 9 and FIG. 3.

First, isolation regions (not shown) are formed by the STI method and Vth control implantation for controlling the threshold voltage of each transistor is performed in regions where an internal transistor 20 and a 2.5V and 3.3V I/O transistor 30 are to be formed. This Vth control implantation is performed by implanting, for example, boron ions as impurities under predetermined conditions. In this case, a 2.5V and 3.3V transistor is to be formed, so there is no need to set impurity concentration in a channel corresponding to each power supply voltage.

As shown in FIG. 4, the entire surface of an Si substrate 11 is then oxidized to form an SiO₂ film 12 in the regions where the internal transistor 20 and the 2.5V and 3.3V I/O transistor 30 are to be formed. In this case, the SiO₂ film 12 is formed so that when an SiO₂ film 13 is formed in the second gate insulator formation step (FIG. 6) described later, the total thickness of the SiO₂ films 12 and 13 will be a predetermined value, that is to say, the thickness corresponding to a power supply voltage of 2.5V.

After that, as shown in FIG. 5, the region where the 2.5V and 3.3V I/O transistor 30 is to be formed is coated with a resist to form a resist film (not shown). Etching is performed with the resist film as a mask to remove the SiO₂ film 12 in the region where the internal transistor 20 is to be formed. By doing so, an Si active region gets exposed on the Si substrate 11. Then the resist film is stripped off and removed.

Next, as shown in FIG. 6, the entire surface of the Si substrate 11 is oxidized again to form the SiO₂ film 13. By performing the above-mentioned steps, gate insulators with different thicknesses are formed in the regions where the internal transistor 20 and the 2.5V and 3.3V I/O transistor 30 are to be formed.

The thickness of the SiO₂ film 13 which functions as the gate insulator of the internal transistor 20 depends on its generation. For example, the thickness of the SiO₂ film 13 of the internal transistor 20 of the 65-nanometer generation should be about 1 to 2 nm.

As stated above, of the SiO₂ films 12 and 13 which function as the gate insulator of the 2.5V and 3.3V I/O transistor 30, the upper SiO₂ film 12 is formed so that the total thickness of the SiO₂ films 12 and 13 will be a predetermined value. For example, in the case of the 2.5V and 3.3V I/O transistor 30, the SiO₂ film 12 is formed so that the total thickness of the SiO₂ films 12 and 13 will be about 5 to 6 nm.

In the conventional method in which a 2.5V I/O transistor and a 3.3V I/O transistor are formed separately, the thicknesses of the gate insulators of the 2.5V I/O transistor and the 3.3V I/O transistor are set to about 5 nm and 7 nm respectively. With the 2.5V and 3.3V I/O transistor 30, however, the total thickness of the SiO₂ films 12 and 13 is about 5 to 6 nm. That is to say, one value close to the thickness of the gate insulator of the 2.5V I/O transistor should be selected.

In selecting the thickness of the gate insulator of the 2.5V and 3.3V I/O transistor 30, preferably the thinnest possible thickness that can ensure reliability estimated on the basis of the TDDB and the like according to an environment in which the LSI 10 is used and the like is adopted.

As shown in FIG. 7, after the gate insulators of the internal transistor 20 and the 2.5V and 3.3V I/O transistor 30 are formed in this way, the gate electrodes 21 and 31 are formed. In this case, gate polycrystalline silicon with predetermined thickness is deposited on the entire surface, a resist coating step and an etching step are performed. By doing so, the gate electrodes 21 and 31 are formed.

After that, a resist film (not shown) is formed only in the region where the internal transistor 20 is to be formed. As shown in FIG. 8, in the region where the 2.5V and 3.3V I/O transistor 30 is to be formed, ion implantation is performed with the gate electrode 31 as a mask to form the LDD regions 34a and 34b and the pocket region 33.

In this case, the LDD regions 34a and 34b are formed by implanting, for example, phosphorus ions at an acceleration energy level of 10 to 40 keV and at a dosage level of 1×10¹³ to 5×10¹⁴ cm⁻² from a direction (shown by dotted arrows in FIG. 8) perpendicular to the Si substrate 11. Arsenic (As) ions may be implanted in place of phosphorus ions to form the LDD regions 34a and 34b.

The pocket region 33 is formed by implanting ions the conduction type of which is the same as that of the impurities used for the Vth control implantation at a certain incident angle to the Si substrate 11, that is to say, from an oblique direction to the Si substrate 11. For example, boron ions are implanted at an acceleration energy level of 10 to 30 keV, at a dosage level of 1×10¹² to 2×10¹³ cm⁻², and at an incident angle (shown by solid arrows in FIG. 8) of 7 to 45° to the normal of the Si substrate 11. The pocket region 33 is formed only outside the LDD region 34a in this way. As a result, the asymmetrical pocket region 33 is formed. That is to say, a profile of impurity concentration which is asymmetrical with the gate electrode 31 as an axis is obtained.

After ions are implanted to form the LDD regions 34a and 34b and the pocket region 33, the resist film formed is stripped off and removed.

A resist film (not shown) is then formed only in the region where the 2.5V and 3.3V I/O transistor 30 is to be formed. As shown in FIG. 9, in the region where the internal transistor 20 is to be formed, ion implantation (shown by dotted arrows in FIG. 9) is performed with the gate electrode 21 as a mask to form the LDD regions 24a and 24b and ion implantation (shown by solid arrows in FIG. 9) is performed with the gate electrode 21 as a mask to form the pocket regions 23a and 23b. After ions are implanted to form the LDD regions 24a and 24b and the pocket regions 23a and 23b, the resist film formed is stripped off and removed.

Next, as shown in FIG. 3, an appropriate insulating film, such as an SiO₂ film, is formed on the entire surface and an etching step is performed. By doing so, the spacers 22 and 32 are formed on the sidewalls of the gate electrodes 21 and 31 respectively.

A resist film (not shown) is then formed in the region where the internal transistor 20 is to be formed. Ion implantation is performed with the gate electrode 31 and the spacer 32 as masks to form the source region 35a and the drain region 35b. The resist film is then stripped off and removed.

Similarly, a resist film (not shown) is formed in the region where the 2.5V and 3.3V I/O transistor 30 is to be formed. Ion implantation is performed with the gate electrode 21 and the spacers 22 as masks to form the source region 25a and the drain region 25b. The resist film is then stripped off and removed.

As a result, the transistor structures shown in FIG. 3 are formed. The subsequent steps are the same as those performed in the ordinary CMOS formation method.

As stated above, by making a profile of impurity concentration in the region between the source region and the drain region asymmetrical and forming the gate insulator with thickness corresponding to the lower power supply voltage, the one transistor which can operate at different power supply voltages can be formed. In addition, compared with conventional LSI manufacturing methods, the number of gate insulator formation steps can be reduced significantly. Therefore, the manufacturing process can be simplified and the costs can be reduced.

The gate insulator thicknesses and the conditions of ion implantation indicated in the above example are simple examples and gate insulator thickness and the conditions of ion implantation will be set properly according to characteristics necessary to the LSI 10 to be formed. Moreover, in the above example, the descriptions are given with the 2.5V and 3.3V I/O transistor 30 as an example. However, an I/O transistor which can operate at other power supply voltages, such as 1.5V and 1.8V or 1.8V and 2.5V, can be formed in the same way by properly selecting the thickness of the gate insulator and the conditions of ion implantation.

Furthermore, in the above example, the descriptions are given with the case where the SiO₂ films are used as gate insulators as an example. However, high-dielectric-constant films may be used as gate insulators to form the internal transistor 20 and the 2.5V and 3.3V I/O transistor 30. In the above example, the optimum film thicknesses are selected with the physical thickness of the SiO₂ films taken into consideration. If high-dielectric-constant films are used, design and fabrication are performed with effective film thickness taken into consideration.

In addition, in the above example, the descriptions are given with the case where the gate electrodes 21 and 31 are formed by using polycrystalline silicon as an example. However, metal gate electrodes may be formed by using metal. In this case, part of the process will be changed, but there is no change in that one transistor can operate at plural kinds of power supply voltages.

Moreover, in the above example, a profile of impurity concentration in the region between the source region 35a and the drain region 35b in the 2.5V and 3.3V I/O transistor 30 is made asymmetrical by forming the pocket region 33 on the source region 35a side of the region between the source region 35a and the drain region 35b. However, a pocket region may also be formed on the drain region 35b side of the region between the source region 35a and the drain region 35b. In this case, a profile of impurity concentration in the region between the source region 35a and the drain region 35b is made asymmetrical by properly controlling impurity concentration in both pocket regions. In addition, impurity concentration in each of the LDD regions 34a and 34b may be controlled properly to make a profile of impurity concentration in the region between the source region 35a and the drain region 35b asymmetrical. Furthermore, a profile of impurity concentration in the region between the source region 35a and the drain region 35b may be made asymmetrical by properly controlling impurity concentration in each of the LDD regions 34a and 34b, the pocket region 33, and the like. Similarly, a profile of impurity concentration in the region between the source region 25a and the drain region 25b in the internal transistor 20 may be made asymmetrical.

In the above example, only the case where the internal transistor 20 and the 2.5V and 3.3V I/O transistor 30 are both formed as nMOSes is shown. However, pMOSes can also be formed through the same steps and the same effect can be obtained by making a profile of impurity concentration in a region between a source region and a drain region asymmetrical.

In the above example, the descriptions are given with the case where the internal transistor 20 and the 2.5V and 3.3V I/O transistor 30 are formed as an example. However, it is a matter of course that the LSI 10 may also include other transistors, such as an I/O transistor in which a profile of impurity concentration in a region between a source region and a drain region is symmetrical.

As has been described in the foregoing, in the present invention a semiconductor device with an asymmetrical impurity concentration profile in which impurity concentration on a source-region side of a region between a source region and a drain region is high and in which impurity concentration on a drain-region side of the region between the source region and the drain region is low is formed. As a result, resistance to hot carriers can be improved and it becomes possible to make one transistor operate at plural kinds of power supply voltages. Therefore, semiconductor integrated circuit devices which can operate at plural kinds of power supply voltages can efficiently be manufactured at a low cost.

In the present invention, a semiconductor device with an impurity concentration profile in which impurity concentration on a source-region side of a region between a source region and a drain region is higher than impurity concentration on a drain-region side of the region between the source region and the drain region can operate at plural kinds of power supply voltages. As a result, a high-performance semiconductor device with high reliability which can be used in an environment where plural kinds of power supply voltages are applied is provided. Moreover, one semiconductor device can operate at plural kinds of power supply voltages. Therefore, by forming a semiconductor integrated circuit device by using such semiconductor devices, the number of kinds of and the number of semiconductor devices included therein can be reduced. In addition, compared with conventional cases where semiconductor devices are formed according to power supply voltages, the manufacturing process can be simplified. This reduces the manufacturing and product costs of semiconductor devices and semiconductor integrated circuit devices.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device comprising:
a gate electrode formed above a semiconductor substrate with a gate insulator between; and
a source region and a drain region formed in the semiconductor substrate,
wherein in an impurity concentration profile of the semiconductor device, impurity concentration on a source-region side of a region between the source region and the drain region is higher than impurity concentration on a drain-region side of the region between the source region and the drain region.

2. The semiconductor device according to claim 1, further comprising a pocket region formed on the source-region side of the region between the source region and the drain region and including impurities the conduction type of which is the same as the conduction type of impurities included in a channel region formed between the source region and the drain region.

3. The semiconductor device according to claim 1, further comprising pocket regions formed on the source-region side and the drain-region side of the region between the source region and the drain region and each including impurities the conduction type of which is the same as the conduction type of impurities included in a channel region formed between the source region and the drain region, wherein the concentration of the impurities included in the pocket region formed on the source-region side of the region between the source region and the drain region is higher than the concentration of the impurities included in the pocket region formed on the drain-region side of the region between the source region and the drain region.

4. The semiconductor device according to claim 1, further comprising an LDD region formed on the drain-region side of the region between the source region and the drain region and including impurities the conduction type of which is the same as the conduction type of impurities included in the source region and the drain region and the concentration of which is lower than the concentration of the impurities included in the drain region.

5. The semiconductor device according to claim 1, further comprising LDD regions formed on the source-region side and the drain-region side of the region between the source region and the drain region and each including impurities the conduction type of which is the same as the conduction type of impurities included in the source region and the drain region and the concentration of which is lower than the concentration of the impurities included in each of the source region and the drain region, wherein the concentration of the impurities included in the LDD region formed on the source-region side of the region between the source region and the drain region is higher than the concentration of the impurities included in the LDD region formed on the drain-region side of the region between the source region and the drain region.

6. The semiconductor device according to claim 1, wherein if a profile of impurity concentration in the region between the source region and the drain region is approximately constant, the thickness of the gate insulator corresponds to thickness required at the time of operation at the lowest power supply voltage of plural kinds of power supply voltages.

7. The semiconductor device according to claim 1, wherein the thickness of the gate insulator corresponds to a thinnest thickness of thicknesses required at the time of operation at plural kinds of power supply voltages.

8. The semiconductor device according to claim 1, wherein the gate insulator is a high-dielectric-constant film.

9. The semiconductor device according to claim 1, wherein the gate insulator is metal.

10. A semiconductor integrated circuit device comprising a plurality of semiconductor devices each including:
a gate electrode formed above a semiconductor substrate with a gate insulator between; and
a source region and a drain region formed in the semiconductor substrate,
wherein:
in each of the plurality of semiconductor devices impurity concentration on a source-region side of a region between the source region and the drain region is higher than impurity concentration on a drain-region side of the region between the source region and the drain region; and
the plurality of semiconductor devices are connected to power supply lines corresponding to plural kinds of power supply voltages.

11. A method for fabricating semiconductor devices which are included in a semiconductor integrated circuit device, each of which includes a gate electrode formed above a semiconductor substrate with a gate insulator between and a source region and a drain region formed in the semiconductor substrate, and which are connected to power supply lines corresponding to plural kinds of power supply voltages, the method comprising the steps of:
introducing impurities for controlling threshold voltage into the semiconductor substrate;
forming the gate insulator with thickness corresponding to thickness required at the time of operation at a lowest power supply voltage of the plural kinds of power supply voltages on the semiconductor substrate in the case of a profile of impurity concentration in a region between the source region and the drain region in each of the semiconductor devices being approximately constant;
forming the gate electrode on the gate insulator;
introducing impurities into the semiconductor substrate with the gate electrode as a mask so that impurity concentration on a source-region side of the region between the source region and the drain region is higher than impurity concentration on a drain-region side of the region between the source region and the drain region at the time of the source region and the drain region being formed;
forming spacers on sidewalls of the gate electrode; and
introducing impurities into the semiconductor substrate with the gate electrode and the spacers as masks to form the source region and the drain region.

12. The method according to claim 11, wherein in the step of introducing impurities into the semiconductor substrate with the gate electrode as a mask, impurities the conduction type of which is the same as the conduction type of impurities included in a channel region formed between the source region and the drain region are introduced on the source-region side of the region between the source region and the drain region.

13. The method according to claim 11, wherein in the step of introducing impurities into the semiconductor substrate with the gate electrode as a mask, impurities the conduction type of which is the same as the conduction type of impurities included in a channel region formed between the source region and the drain region are introduced on the source-region side and the drain-region side of the region between the source region and the drain region so that impurity concentration on the source-region side of the region between the source region and the drain region will be higher than impurity concentration on the drain-region side of the region between the source region and the drain region.

14. The method according to claim 11, wherein in the step of introducing impurities into the semiconductor substrate with the gate electrode as a mask, impurities the conduction type of which is the same as the conduction type of impurities included in the source region and the drain region are introduced on the drain-region side of the region between the source region and the drain region so that impurity concentration on the drain-region side of the region between the source region and the drain region will be lower than impurity concentration in the drain region.

15. The method according to claim 11, wherein in the step of introducing impurities into the semiconductor substrate with the gate electrode as a mask, impurities the conduction type of which is the same as the conduction type of impurities included in the source region and the drain region are introduced on the source-region side and the drain-region side of the region between the source region and the drain region so that impurity concentration on each of the source-region side and the drain-region side of the region between the source region and the drain region will be lower than impurity concentration in each of the source region and the drain region and so that impurity concentration on the source-region side of the region between the source region and the drain region will be higher than impurity concentration on the drain-region side of the region between the source region and the drain region.

16. The method according to claim 11, wherein in the step of forming the gate insulator, the thickness of the gate insulator is set to a thinnest thickness of thicknesses required at the time of operation at the plural kinds of power supply voltages.

17. A method for fabricating a semiconductor integrated circuit device including a plurality of semiconductor devices each of which includes a gate electrode formed above a semiconductor substrate with a gate insulator between and a source region and a drain region formed in the semiconductor substrate, and which are connected to power supply lines corresponding to plural kinds of power supply voltages, the method comprising the steps of:
introducing impurities for controlling threshold voltage into the semiconductor substrate;
forming the gate insulator with thickness equal to thickness required at the time of operation at a lowest power supply voltage of the plural kinds of power supply voltages on the semiconductor substrate in the case of a profile of impurity concentration in a region between the source region and the drain region in each of the plurality of semiconductor devices being approximately constant;
forming the gate electrode on the gate insulator;
introducing impurities into the semiconductor substrate with the gate electrode as a mask so that impurity concentration on a source-region side of the region between the source region and the drain region is higher than impurity concentration on a drain-region side of the region between the source region and the drain region at the time of the source region and the drain region being formed;
forming spacers on sidewalls of the gate electrode; and
introducing impurities into the semiconductor substrate with the gate electrode and the spacers as masks to form the source region and the drain region.
